(19) United States
(12) Patent Application Publication
(10) Pub. No.: US 2024/0387243 A1
(43) Pub. Date: Nov. 21, 2024

(54) METHOD FOR PREPARING A SUPPORT SUBSTRATE PROVIDED WITH A CHARGE-TRAPPING LAYER

(71) Applicant: Soitec, BERNIN (FR)

(72) Inventors: Youngpil Kim, Bernin (FR); Oleg Kononchuk, Bernin (FR); Chee Hoe Wong, Bernin (FR)

(21) Appl. No.: 18/688,606

(22) PCT Filed: Oct. 19, 2022
(86) PCT No.: PCT/FR2022/051974

§ 371 Date: Mar. 1, 2024

(30) Foreign Application Priority Data
Nov. 9, 2021 (FR) FR2111876

(51) Int. Cl. H01L 21/763; H01L 21/762; H10N 30/072

(52) U.S. Cl. CPC H01L 21/763; H01L 21/76251; H10N 30/072

(57) ABSTRACT

A method for preparing a support substrate having a charge-trapping layer includes introducing a monocrystalline silicon base substrate into a chamber of deposition equipment and, without removing the base substrate from the chamber and while flushing the chamber with a carrier gas, performing the following successive steps:
forming a dielectric layer on the base substrate by introducing a reactive gas into the chamber over a first time period; and
forming a polycrystalline silicon charge-trapping layer directly on the dielectric layer by introducing a precursor gas containing silicon into the chamber over a second time period, subsequent to the first time period. The time for which the dielectric layer is exposed only to the carrier gas, between the first time period and the second time period, is less than 30 seconds and the formation of the charge-trapping layer is performed at a temperature strictly between 1010° C. and 1200° C.

### CROSS REFERENCE TO RELATED APPLICATIONS

This application is a national phase entry under 35 U.S.C. § 371 of International Patent Application PCT/FR2022/051974, filed Oct. 19, 2022, designating the United States of America and published as International Patent Publication WO 2023/084168 A1 on May 19, 2023, which claims the benefit under Article 8 of the Patent Cooperation Treaty to French Patent Application Serial No. FR2111876, filed Nov. 9, 2021.

### TECHNICAL FIELD

The present disclosure relates to a process for preparing a support substrate comprising a charge-trapping layer. The present disclosure also relates to a process for transferring a thin layer onto such a support substrate to form a composite substrate. These support and composite substrates have a notable application in the field of radiofrequency integrated devices, i.e., electronic devices that process signals whose frequency is between about 3 kHz and 300 GHz, for example, in the field of telecommunications (telephony, Wi-Fi, BLUETOOTH®, etc.).

### BACKGROUND

To ward against or limit the electromagnetic coupling that can take place between an electronic device and the support substrate of a silicon-on-insulator (SOI) substrate on which the device is formed, it is known practice to insert between the buried dielectric layer and the SOI support, directly under the dielectric layer, a charge-trapping layer. This layer may consist, for example, of a 0.1 to 10 micron layer of polycrystalline silicon formed on a single-crystal silicon base substrate, which is often chosen to be highly resistive (i.e., having a resistivity of greater than 500 ohm·cm, or even greater than 1000 ohm·cm). The boundaries of the grains forming the polycrystal then constitute traps for the charge carriers, which may come from the trapping layer itself or from the underlying substrate. In this way, the appearance of a conductive plane under the insulator is prevented. The manufacture of this type of well-known SOI substrate is described, for example, in FR 2860341, FR 2933233, FR 2953640, US 2015/115480, U.S. Pat. Nos. 7,268,060, 6,544,656 or WO 2020/008116.

In order to promote the creation and avoid the recrystallization of the charge-trapping layer formed on the single-crystal silicon base substrate, it is known practice to form on this base substrate, and prior to the formation of the trapping layer by deposition, an amorphous dielectric layer, typically a silicon dioxide layer. The amorphous dielectric layer makes it possible to preserve the polycrystalline nature of the trapping layer by preventing its recrystallization when the temperature of the stack is raised.

EP 3136421 thus proposes to form a polycrystalline silicon trapping layer on a base substrate with a resistivity of 700 ohm·cm. The base substrate is oxidized by simple cleaning or by dry oxidation. The trapping layer is then formed in two successive deposition steps using a trichlorosilane precursor gas. The first step is directed toward forming a seed layer at a relatively low temperature, below 1010° C., directly on the silicon oxide layer, and the second step is performed at a higher temperature than the first step. According to the document, this approach makes it possible to form the trapping layer rapidly, and without excessively deforming the base substrate, which might prevent the assembly of this substrate by molecular adhesion when it is intended to form a support substrate for a silicon-on-insulator substrate.

EP 3309819 proposes to form, over the course of two successive steps performed in different items of equipment, a dielectric layer on an exposed face of a base substrate and a charge-trapping layer on the dielectric layer. The charge-trapping layer is formed at a temperature between 1050° C. and 1200° C.

For its part, EP 2503592 envisages producing such layers in situ. In the document, the trapping layer is formed on a dielectric layer of a silicon base substrate without removing the base substrate from the equipment used to form this stack. It may be a chamber of an epitaxy frame.

In this approach, the base substrate is placed in the chamber of the equipment, and an oxidizing gas is circulated through the chamber to superficially form the dielectric layer during an oxidation step performed at a temperature of about 1100° C. Next, without removing the base substrate from the chamber, a carrier gas is circulated to flush out the oxidizing gas and the temperature of the chamber and/or substrate is brought to a relatively low deposition temperature, on the order of 900° C. or less.

Once the oxidizing atmosphere has been flushed out by the carrier gas and the deposition temperature has been established, the precursor gas containing silicon is introduced to gradually form the polycrystalline silicon layer on the dielectric layer by deposition. By sequencing the introduction of the gases into the chamber in this manner, the introduction of the precursor gas before the oxidizing gas has been flushed out and before the temperature is well established at the target temperature of about 900° C. or less is avoided, and premature deposition of polycrystalline silicon that would not have the required qualities is prevented.

However, the formation of a polycrystalline silicon layer at a relatively low deposition temperature is particularly slow, of the order of 0.3 micron per minute at 900° C. Specifically, it is well known that the deposition rate generally increases with temperature. To improve this deposition rate, and thus the manufacturing time of the support equipped with the trapping layer, it may be envisaged, as proposed in EP 3136421, to form only a seed portion of the trapping layer at low temperature, the remainder of the layer then being able to be formed at a relatively higher temperature, and thus more quickly.

Although such an approach does indeed improve the rate of production of support substrates, the formation of the seed layer remains a particularly time-consuming step. It is generally desirable to further increase the production rate, without of course compromising the quality of the support.

### BRIEF SUMMARY

One aim of the present disclosure is to propose a process for preparing a support substrate equipped with a charge-trapping layer, which at least partly addresses this problem. More specifically, one aim of the present disclosure is to propose a process for preparing a support substrate equipped with a charge-trapping layer, the implementation time of which, for a comparable quality, is reduced compared with the processes of the prior art. Even more specifically, one aim of the present disclosure is to propose a process for preparing a support substrate equipped with a charge-trapping layer that does not require a seed portion formed at a relatively low temperature of about 1010° C. or less.

In order to achieve this aim, the object of the present disclosure is to propose a process for preparing a support substrate equipped with a charge-trapping layer. The process comprises the introduction of a single-crystal silicon base substrate having a resistivity of greater than 500 ohm·cm into a chamber of deposition equipment and, without removing the base substrate from the chamber and while flushing the chamber with a carrier gas, performing the following successive steps:
forming a dielectric layer on an exposed face of the base substrate by introducing a reactive gas into the chamber over a first time period;
forming a polycrystalline silicon charge-trapping layer directly on the dielectric layer by introducing a precursor gas containing silicon into the chamber over a second time period subsequent to the first time period.

According to the present disclosure, the time for which the dielectric layer is exposed only to the carrier gas, between the first time period and the second time period, is less than 30 seconds. Also according to the present disclosure, the step of forming the charge-trapping layer is performed at a temperature strictly between 1010° C. and 1200° C.

By limiting the time of exposure of the dielectric layer to the carrier gas alone, between the first time period and the second time period, the surface state of this layer is conditioned or maintained to make it particularly suitable for receiving a quality polycrystalline silicon layer, identical to that obtained at a much lower temperature in an approach in accordance with the prior art. This surprising result makes it possible to grow the trapping layer at a high growth rate for an equivalent quality, and thus to form a support substrate at an improved rate compared with an approach in accordance with the prior art.

According to other advantageous and non-limiting features of the present disclosure, taken alone or in any technically feasible combination:
the carrier gas comprises or consists of hydrogen;
the precursor gas containing silicon is chosen from the list including silane, disilane, trichlorosilane, dicholorosilane and silicon tetrachloride;
the dielectric layer is made of silicon oxide and the reactive gas comprises between 0.1% and 10% oxygen in a neutral gas such as argon;
the step of forming the dielectric layer is performed at a temperature of between 1010° C. and 1150° C.;
the dielectric layer has a thickness of greater than 0.5 nm;
the step of forming the charge-trapping layer is performed at a temperature above 1050° C. or even above 1100° C.;
the charge-trapping layer and the dielectric layer are formed at respective temperatures that are identical to within 50° C.;
the time for which the dielectric layer is exposed only to the carrier gas is less than 20 seconds or even less than 15 seconds;
the charge-trapping layer has a thickness of between 0.1 and 10 microns.

### BRIEF DESCRIPTION OF THE DRAWINGS

Other features and advantages of the present disclosure will become apparent from the following detailed description of embodiments of the present disclosure, which is given with reference to the appended figures, in which:

FIG. 1 shows a support substrate in accordance with a first embodiment;

FIG. 2 shows a support substrate in accordance with a second embodiment;

FIG. 3 shows a composite substrate that comprises a support substrate in accordance with the present disclosure; and

FIG. 4 illustrates the sequence of the two main steps of a process in accordance with the present disclosure.

### DETAILED DESCRIPTION

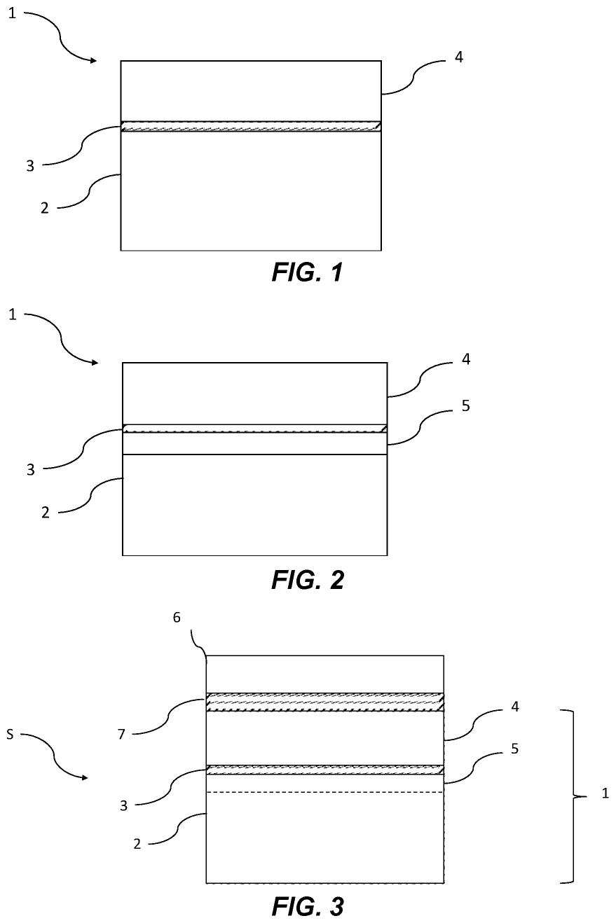

With reference to FIG. 1, a support substrate 1 of one embodiment comprises a base substrate 2, a dielectric layer 3 arranged on the base substrate 2, and a charge-trapping layer 4 arranged on and in contact with the dielectric layer 3.

The support substrate 1 may be in the form of a circular wafer of standardized size, for example, 200 mm or 300 mm or even 450 mm in diameter. However, the present disclosure is not in any way limited to these dimensions or to this form.

The base substrate 2 consists of single-crystal silicon and is several hundred microns thick. Preferably, the base substrate 2 has a high resistivity, strictly greater than 500 or greater than 1000 ohm·cm, and even more preferably greater than 3000 ohm·cm in some embodiments. This limits the density of charges, holes or electrons, which are liable to move in the base substrate 2, and thus deteriorate the RF performance of the final substrate S. It may be, for example, a CZ substrate with a low interstitial oxygen content, which has, as is well known per se, a resistivity that may be greater than 1000 ohm·cm.

However, the present disclosure is not limited to a base substrate 2 having such a resistivity, and it also affords RF performance benefits when the base substrate 2 has a more compliant resistivity of less than or equal to 500 ohm·cm, or 100 ohm·cm or less. It may be in this case a more standard single-crystal CZ substrate with a resistivity of less than 500 ohm·cm. This approach is advantageous in that such a substrate can be readily and inexpensively sourced.

With reference to FIG. 2, the support substrate may also comprise, notably when the base substrate 2 has a resistivity of less than or equal to 500 ohm·cm, an intrinsic single-crystal silicon layer 5, i.e., a layer that is not intentionally doped and that is thus particularly resistive, arranged between the base substrate 2 and the dielectric layer 3. The intrinsic single-crystal silicon layer 5 advantageously has a resistivity of greater than 2000 ohm·cm, which may even reach 20 kohm·cm or more. Its thickness may be between 0.5 and 100 microns, and preferably between 5 and 20 microns.

The dielectric layer 3, for example, made of silicon oxide or silicon nitride, has a thickness of greater than 0.5 nm, for example, between 0.5 nm and 50 nm. This amorphous dielectric layer 3 makes it possible to form the charge-trapping layer 4 in a polycrystalline form, and to avoid or limit the recrystallization of this layer when the support substrate 1 is exposed to a high temperature, during the formation of this layer 4 or during the subsequent heat treatments, which the support substrate 1 is made to undergo.

The support substrate 1 also includes a charge-trapping layer 4 made of polycrystalline silicon, arranged on and directly in contact with the dielectric layer 3. The charge-trapping layer 4 has a resistivity of greater than 500 ohm·cm, preferably greater than 1 kohm·cm. As mentioned in the introduction to the present disclosure, the function of the trapping layer is to trap charge carriers that may be present in the support substrate 1 and to limit their mobility. The charge-trapping layer 4 typically has a thickness of between 0.1 micron and 10 microns, or even more.

On account of its non-crystalline nature, the trapping layer 4 has structural defects such as dislocations, grain boundaries, amorphous zones, interstices, inclusions, pores defining the grains of the layer, etc. These structural defects form traps for the charges that are liable to circulate in the material, for example, at the level of incomplete or pending chemical bonds. Conduction in the trapping layer is thus prevented and the support substrate 1 consequently has high radiofrequency performance. This performance may be established by a “second harmonic distortion” characterization measurement on a support prepared in this manner. This measurement is typically performed at 900 MHz. It is generally sought for the distortion measurement to be less than −70 dB so that the support substrate can be considered as having high radiofrequency performance.

This characterization measurement, which is described in detail in the document entitled “White paper—RF SOI wafer characterization” of January 2015, published by Soitec and in US 2015/0168326, is particularly relevant since it is very representative of the performance of an RF integrated device that would be formed on a composite substrate incorporating the characterized support substrate.

The size of the grains of the polycrystalline silicon charge-trapping layer 4 is advantageously between 50 nm (below which their thermal stability is no longer ensured and there is a risk of their recrystallization in temperature) and 2000 nm (above which the RF performance of the support substrate is affected).

In any case, and irrespective of the precise characteristics of the grains of the trapping layer 4, it has a high resistivity of greater than 500 ohm·cm. To this end, the trapping layer 4 is not intentionally doped, i.e., it has a charge-carrying dopant concentration of less than 2E13 atoms per cubic centimeter. It may be rich in nitrogen or carbon so as to improve its resistivity characteristic.

For the sake of completeness, FIG. 3 shows a composite substrate S that comprises a support substrate 1 in accordance with the present disclosure. As emerges very clearly from this figure, the composite substrate comprises, on the support substrate 1, a thin film 6 preferably made of crystalline material. For example and without limitation, the thin film 6 may be made of a semiconductor material, such as silicon, or of a piezoelectric material, such as lithium tantalate (LiTaO₃) or lithium niobate (LiNbO₃).

The composite substrate S of FIG. 3 may be formed in many ways from the support substrate 1, but this formation advantageously includes a step of transferring the thin film 6 onto this support substrate. As is well known per se, this transfer is usually performed by assembling “main” faces of a donor substrate and of the support substrate 1. It is generally envisaged to provide at least one of these faces with a dielectric bonding layer 7, typically of silicon oxide, which may be formed by heat treatment or by deposition. The assembly preferably involves molecular adhesion bonding.

After this assembly step, the thickness of the donor substrate is reduced so as to form the thin film 6. This reduction step may be performed by mechanical or chemical thinning. It may also be performed by fracturing in a fragile zone introduced beforehand into the donor substrate, for example, in accordance with the principles of the Smart Cut™ technology.

Finishing steps of the thin film 6, such as a polishing step, a heat treatment under a reducing or neutral atmosphere or sacrificial oxidation may be performed in sequence with the thickness reduction step.

It is noted that the donor substrate may be a simple substrate, i.e., a substrate not including integrated devices, or alternatively the donor substrate may have been pretreated so as to produce integrated devices on its surface.

The process for preparing the support substrate 1, which was the subject of the preceding section of the present disclosure, is now disclosed.

The single-crystal silicon base substrate 2 is introduced into a chamber of deposition equipment.

This equipment may correspond to epitaxial deposition equipment. It comprises a susceptor arranged in the chamber to receive the base substrate and to expose one of its faces to the atmosphere and to the gas streams circulating in the chamber. The susceptor may be mobile, and may notably have a rotational movement to angularly unify the exposure of the free face of the base substrate 2 to the gas stream. To enable the introduction of these streams and the control of the atmosphere contained in the chamber, the chamber is equipped with a plurality of inlet ports, and at least one outlet port. The chamber is also equipped with a device for heating the substrate, the gases and/or the walls of the chamber, for example, lamps emitting radiation capable of heating the free surface of the base substrate. A plurality of pipes fluidly connected to the inlet ports of the chamber allows the introduction at a controlled rate of the gases for treating the base substrate 2. The gas is notably a reactive, oxidizing or nitriding gas, a carrier gas, for example, a mixture of argon and hydrogen, or hydrogen, and a precursor gas containing silicon. This precursor gas may be, for example, silane, disilane, trichlorosilane, dicholorosilane and silicon tetrachloride. The equipment may of course be equipped with other pipes for introducing other gases into the chamber. The equipment is also provided with a control device configured to control all the parameters (flow rates of the various gases, temperature, pressure, etc.) of the preparation process performed.

The process for preparing the support substrate in accordance with the preceding section of the present disclosure notably comprises two main steps, which are performed without removing the base substrate 2 from the chamber of the equipment. As a result, the base substrate is not exposed to any gases or atmosphere other than those introduced or present in the chamber throughout the preparation process.

As is well known per se, the carrier gas CG is introduced into the chamber at a given flow rate through an inlet port to flush it throughout the process for preparing the donor substrate, notably during the two main steps of this process.

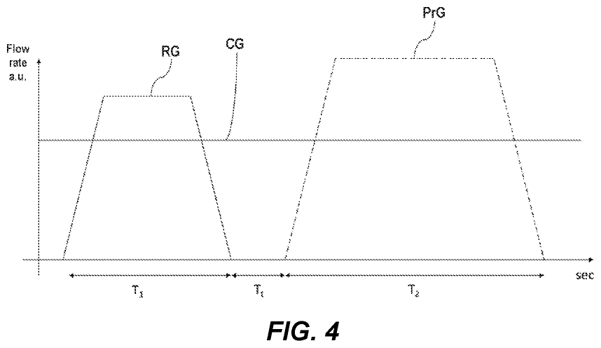

In a first step, and as illustrated in FIG. 4, the dielectric layer 3 is formed on the exposed face of the base substrate 2 by introducing into the chamber, and at a chosen flow rate, a reactive gas RG, over a first time period T1. The heating device is controlled so that the dielectric layer is formed at a temperature typically between 900° C. and 1150° C., and preferably between 950° C. and 1100° C. Depending on the nature of the dielectric layer that it is desired to form, for example, silicon dioxide or silicon nitride, this reactive gas may be formed from an oxidizing gas or a nitriding gas. Preferably, the dielectric layer is made of silicon oxide, in which case the reactive gas may comprise, for example, between 0.1% and 10% oxygen in a neutral gas such as argon. The oxidizing atmosphere in the chamber is maintained for a chosen time (the first time period) depending on the desired thickness of the dielectric layer 3. Preferably, the dielectric layer 3 has a thickness of greater than 0.5 nm.

Then, in a second step following the first step, a charge-trapping layer 4 made of polycrystalline silicon is formed directly on the dielectric layer 3 by introducing the precursor gas PrG containing silicon into the chamber at a chosen flow rate over a second time period T2 subsequent to the first time period T1. The amorphous nature of the dielectric layer prevents the crystallization of the trapping layer that forms during this second step, which could occur if this dielectric layer were not present.

The sequence of the first and second steps is performed in a controlled manner, notably so as to avoid the mixing of the reactive and precursor gases, which could cause undesired chemical reactions in the chamber and prevent the deposition of a trapping layer of the desired quality. In other words, and as may clearly be seen in FIG. 4, the first step during which the reactive gas forms the atmosphere of the chamber does not overlap with the second step during which the precursor gas forms the atmosphere of the chamber.

On conclusion of the first step, and during the transition period Tt that separates the end of the first time period from the start of the second time period, the carrier gas, which constantly flushes the chamber throughout the preparation process, flushes the reactive gas out of the chamber. This transition period is also used to adjust the temperature of the chamber and/or of the substrate, in the case where the temperature of the first step is different from the temperature of the second step. In a second stage, and after this transition period Tt, the precursor gas is introduced into the chamber. When this gas is introduced into the chamber, the atmosphere and temperature of this chamber are thus perfectly suited to the formation of a quality charge-trapping layer 4. The carrier gas and the precursor gas flow simultaneously through the chamber for the remainder of this second process step.

Conventionally, and as reported in the introduction to the present disclosure, the growth of the trapping layer is performed, at least on a seed portion in contact with the dielectric layer, at a relatively low temperature of 1010° C. or less so as to obtain a layer of satisfactory quality. This quality is notably measured by measuring the second harmonic distortion. It is also measured by the stress in the charge-trapping layer 4, which may tend to deform the substrate if it is too great. It is generally sought to limit this deformation (typically a “bow” in semiconductor technology), for a substrate 300 mm in diameter, to less than 200 microns or even less than 100 microns.

It has been observed that it was possible to obtain a trapping layer 4 of a quality entirely similar to that of the state of the art, by performing this second step at a relatively higher temperature, strictly greater than 1010° C., as long as the duration of the transition period Tt did not exceed 30 seconds. In other words, when the time for which the dielectric layer 3 is exposed only to the carrier gas is less than 30 seconds, the formation of the charge-trapping layer 4 can be performed at a temperature above 1010° C., and typically between 1010° C. and 1200° C., while at the same time having an acceptable quality of this layer, both in terms of deformation and in terms of second harmonic distortion measurement.

It is thus seen that by limiting the time of exposure of the dielectric layer 3 to the carrier gas alone, between the first time period and the second time period, the surface state of this layer 3 is conditioned or maintained to make it particularly suitable for the direct growth of the trapping layer 4 at a much higher temperature than in the state of the art. To this end, it may be advantageous to limit the time for which the dielectric layer 3 is exposed only to the carrier gas to 20 seconds or even 15 seconds.

It should also be noted that by limiting this time, the dissolution of the dielectric layer 3, which may occur during the transition period, is avoided or limited. This dissolution leads to a loss of thickness of this dielectric layer, this loss being proportional to the duration of the transition period Tt raised to the power n, (Tt)\hat{ }n, n possibly ranging between 2 and 4 depending on the temperature, the initial thickness of the dielectric layer and the flow rate of the carrier gas. When the duration of the transition period is excessive, the thickness of the dielectric layer is liable to become insufficient to allow the formation of a charge-trapping layer of satisfactory quality.

It is recalled that a relatively high temperature of formation of the trapping layer is an important characteristic in that it can then be formed much more quickly, for an equivalent quality. Thus, the growth rate at 950° C. is on the order of 0.8 micron per minute, on the order of 1.25 microns per minute at 1000° C. and on the order of 2 microns per minute at 1100° C., which is appreciably higher than the 0.3 micron per minute observed at 900° C. This significantly improves the rate of production of a support substrate relative to the rate obtained using the prior art processes. This is notably the case when the trapping layer is relatively thick, greater than 2 microns.

Thus, and in order to target a large growth rate of the trapping layer 4, the step of forming this layer 4 is preferably performed at a temperature strictly greater than 1010° C., than 1050° C., or greater than 1100° C.

Irrespective of the temperature chosen during this step of forming the trapping layer 4, it is performed for a time period that is sufficient to form a target thickness of polycrystalline silicon directly on the dielectric layer 3.

In order to limit the loss of thickness of the dielectric layer 3 during the transition period Tt, the treatment temperature may be lowered during this period, for example, by 50° C. relative to the temperature of the first time period.

Advantageously, the charge-trapping layer 4 and the dielectric layer 3 are formed at respective temperatures that are identical to within 50° C. For example, the two steps may be performed in sequence as presented previously, while maintaining the same temperature of 1050° C. or 1100° C. for the first and second steps. Since it is not necessary to raise or lower the temperature between the two steps, the duration of the transition period can be reduced more easily, to below 30 seconds, for example, below 20 seconds or even 15 seconds.

The dielectric layer 3 may be formed at a temperature above, below or equal to the temperature of formation of the charge-trapping layer 4.

Optionally, the first step of forming the dielectric layer 3 may be preceded by deoxidation annealing of the base substrate under a reducing or weakly reducing atmosphere, at a temperature of between 900° C. and 1200° C., to remove any native oxide that may be present on the surface of the base substrate 2. This annealing may be performed while only the carrier gas is flowing in the chamber, for a time of several seconds to several minutes, depending on the chosen temperature, in order to remove this native oxide.

This step is particularly useful when the base substrate 2 has a relatively low resistivity, for example, less than or equal to 500 ohm·cm, and when it is favorable to provide an intrinsic silicon epitaxial layer 5 on the base substrate 2. In such a case, the treatment process comprises, between the deoxidation annealing and the first step of forming the dielectric layer 3, the formation of this intrinsic silicon epitaxial layer 5 on the base substrate 2, at an epitaxial temperature typically between 900° C. and 1200° C. To this end, the carrier gas and precursor gas containing silicon can be simultaneously circulated in the chamber.

Needless to say, these steps of deoxidation annealing and/or epitaxial layer formation are also performed in situ, i.e., without removing the base substrate 2 from the chamber of the equipment and without exposing the free surface of the support substrate 1 under preparation to gases or atmospheres other than those introduced into or present in the chamber throughout the process.

Needless to say, the present disclosure is not limited to the embodiments described, and implementation variants may be applied thereto without departing from the scope of the invention as defined by the claims.

1.-10. (canceled)

11. A method of preparing a support substrate having a charge-trapping layer, the method comprising introducing a single-crystal silicon base substrate having a resistivity of greater than 500 ohm·cm into a chamber of deposition equipment and, without removing the base substrate from the chamber and while flushing the chamber with a carrier gas, performing the following successive steps:
forming a dielectric layer on an exposed face of the base substrate by introducing a reactive gas into the chamber over a first time period; and
forming a polycrystalline silicon charge-trapping layer directly on the dielectric layer by introducing a precursor gas containing silicon into the chamber over a second time period, subsequent to the first time period;
wherein the time for which the dielectric layer is exposed only to the carrier gas, between the first time period and the second time period, is less than 30 seconds, and wherein the step of forming the charge-trapping layer is performed at a temperature strictly between 1010° C. and 1200° C.

12. The method of claim 11, wherein the carrier gas comprises hydrogen.

13. The method of claim 12, wherein the precursor gas containing silicon is chosen from among the group consisting of silane, disilane, trichlorosilane, dicholorosilane and silicon tetrachloride.

14. The method of claim 13, further comprising forming the dielectric layer to comprise silicon oxide and selecting the reactive gas to comprise between 0.1% and 10% oxygen in a neutral gas such as argon.

15. The method of claim 14, wherein the step of forming the dielectric layer is performed at a temperature of between 1010° C. and 1150° C.

16. The method of claim 15, further comprising forming the dielectric layer to have a thickness of greater than 0.5 nm.

17. The method of claim 16, wherein the step of forming the charge-trapping layer is performed at a temperature above 1050° C.

18. The method of claim 17, further comprising forming the charge-trapping layer and the dielectric layer at respective temperatures that are identical to within 50° C.

19. The method of claim 18, wherein the time for which the dielectric layer is exposed only to the carrier gas is less than 20 seconds.

20. The method of claim 19, further comprising forming the charge-trapping layer to have a thickness of between 0.1 and 10 microns.

21. The method of claim 11, wherein the precursor gas containing silicon is chosen from among the group consisting of silane, disilane, trichlorosilane, dicholorosilane and silicon tetrachloride.

22. The method of claim 11, further comprising forming the dielectric layer to comprise silicon oxide and selecting the reactive gas to comprise between 0.1% and 10% oxygen in a neutral gas such as argon.

23. The method of claim 11, wherein the step of forming the dielectric layer is performed at a temperature of between 1010° C. and 1150° C.

24. The method of claim 11, further comprising forming the dielectric layer to have a thickness of greater than 0.5 nm.

25. The method of claim 11, wherein the step of forming the charge-trapping layer is performed at a temperature above 1050° C.

26. The method of claim 25, wherein the step of forming the charge-trapping layer is performed at a temperature above 1100° C.

27. The method of claim 11, further comprising forming the charge-trapping layer and the dielectric layer at respective temperatures that are identical to within 50° C.

28. The method of claim 11, wherein the time for which the dielectric layer is exposed only to the carrier gas is less than 20 seconds.

29. The method of claim 28, wherein the time for which the dielectric layer is exposed only to the carrier gas is less than 15 seconds.

30. The method of claim 11, further comprising forming the charge-trapping layer to have a thickness of between 0.1 and 10 microns.
